(19) United States
(12) Patent Application Publication
(10) Pub. No.: US 2001/0020750 A1
(43) Pub. Date: Sep. 13, 2001

(54) Semiconductor wafer and method of specifying crystallographic axis orientation thereof

(76) Inventors: Teiichirou Chiba, Kanagawa-ken (JP); Akira Mori, Kanagawa-ken (JP)

Correspondence Address: Michael S. Leonard, Bell, Boyd & Lloyd, Three First National Plaza, 70 West Madison Street, Suite 3300, Chicago, IL, 60602-4207, US

(21) Appl. No.: 09/795,940

(22) Filed: Feb. 28, 2001

(30) Foreign Application Priority Data
Mar. 7, 2000 (JP) 2000-61666

(51) Int. Cl. H01L 21/76; H01L 23/544; H01L 21/78; H01L 21/46

(52) U.S. Cl. 257/797; 438/401; 438/462; 438/975

(57) ABSTRACT

A semiconductor wafer having dot mark groups which are excellent in optical visibility and which have a peculiar configuration indicating the orientation of a crystallographic axis and a method of specifying the orientation of a crystallographic axis by the dot mark groups are provided. After a plurality of marks in a dot shape a part of which rising from the wafer surface within the predetermined region of a semiconductor wafer are formed, a group of epitaxial growth dot marks in which s single crystal is formed on the entire surface of the foregoing semiconductor wafer by the epitaxial growth, and a group of non-epitaxial growth dot marks in which no or little epitaxial growth is formed are made. By extracting the dot mark which is most excellent in visibility in the foregoing group of non-epitaxial growth dot marks, the orientation of a crystallographic axis is spsecified from this dot mark and the wafer center.

### BACKGROUND OF THE INVENTION

1. Field of the Invention

The present invention relates to a semiconductor wafer which has a group of dot marks having a specific configuration on a part of a wafer surface and a method of specifying its crystallographic axis orientation, and specifically, the present invention relates to a semiconductor wafer in which a mark itself is prominent in optical visibility, moreover, the same wafer has a group of dot marks having a specific configuration with which an orientation of a crystallographic axis of the same semiconductor wafer can be distinguished and a method of specifying an orientation of a crystallographic axis of the same wafer.

2. Description of the Related Art

The electric characteristics of silicon, which is a substrate material of a semiconductor integrated circuit, depend on an orientation of a crystallographic axis. Therefore, upon baking a circuit in a silicon wafer, which is a general substrate material of a semiconductor, it is necessary to adapt its circuit pattern to an orientation of a crystallographic axis. Hence, conventionally, a mark indicating an orientation of a crystallographic axis is appended on a semiconductor wafer.

As a typical instance of this mark, there is an orientation flat that one portion of a semiconductor wafer in a circular plate shape is cut off in a sine direction perpendicular to an orientation of a crystallographic axis. This orientation flat is generally used for a semiconductor wafer of 150 mm in diameter, and also partially used for a wafer of 200 mm in diameter. Recently, due to upsizing of a semiconductor wafer (equal to or more than 200 mm in diameter), on some portion of a circumference of a semiconductor wafer, a notch in a V shape is formed as the foregoing mark while adapting an orientation of a crystallographic axis to the direction of a straight line connecting the vertex of the notch and the center of the semiconductor. This is because, as the semiconductor wafer is made larger, device manufactures have a desire to obtain semiconductor integrated circuits as many as possible, and the influence on integration extent due to the occurrence of subtle irregularity of film forming processing during forming circuit caused by the formation of the orientation flat could not be ignored.

With regard to the tendency that the influence on an integration extent of circuits cannot be ignored, it is similar in the case of an orientation mark by the foregoing notch. Moreover, since the notch forms a minute space and dust such as contaminant tends to accumulate in a notch portion, in consideration of even its influence, recently, there is a movement that an orientation of a crystallographic axis in a semiconductor wafer is indicated by laser marker while avoiding these markings. However, from the reason why a marking of a crystallographic orientation by laser marker leads to an increase of cost accompanied with alternation of the existing facilities, in the present situation, the laser marker method is not standardized as the foregoing marking technology.

On the other hand, in any semiconductor wafer manufacturers and semiconductor manufacturers, when management information such as ID information, processing history and electric characteristics is marked on a surface of a part of the wafer, in many cases, a laser marker is used. Considering this situation and if a mark simply marked by the existing laser marker directly indicates an orientation of a crystallographic axis of a semiconductor wafer, it is unnecessary to previously and precisely measure an orientation of a crystallographic axis using X-ray, and since any cutting off of a semiconductor wafer is not accompanied with neither, it can satisfy both requirements of wafer manufacturers and semiconductor manufacturers.

### SUMMARY OF THE INVENTION

The present invention has been developed based on these circumstances, and a specific object of the present invention is to provide a semiconductor wafer having an orientation mark not receiving any influence by cutting off or the like, capable of recognizing an orientation of a crystallographic axis and capable of being used as a variety of management information, and a method of specifying the orientation of the crystallographic axis by combination of an improved laser marking technology and a conventional general semiconductor fabrication technology.

The present inventors have already proposed a dot mark having specific configuration different from a dot mark configuration of a concave opening type by a conventional laser marking technology and a method of forming the dot mark as disclosed in Japanese Patent Application No. 10-334009. The dot mark of the invention of this prior application is the one which is marked on the surface of the item subjected to marking using laser beam as an energy source, the center portion of the individual dot marks have a rising portion rising upward from the surface of the item subjected to marking and is a extremely minute dot mark in the range of 1 to 15 μm in length along its marking surface and 0.01 to 5 μm of the foregoing rising portion in height. Whereas it is such a minute dot mark, it is optically extremely excellent in visibility from its configuration.

In this way, when the present inventors have formed a single crystal layer by epitaxial growth on a mark formation surface of the semiconductor wafer on which the dot mark having this rising portion is formed, it has been found that it has changed to a different configuration compared to the initial dot configuration. Then, an experiment that has changed the thickness of a single crystal made by the foregoing epitaxial growth has been repeated as well as a marking region has been altered along the marking surface. As a result of it, in a predetermined marking region, it has been found out that even within the same region, the dot marks are divided into a dot mark group in which a single crystal is grown on the surface and another dot mark group in which a signal crystal is little grown.

In addition, although a configuration of each dot mark of the foregoing dot mark groups changed by epitaxial growth is varied by the thickness of its growth layer, if the growth layer has an appropriate thickness, a configuration of each dot mark is formed in a poly pyramid shape or a truncated poly pyramid shape having a clear ridge line. Then, the present inventors have inferred that there is any relationship between the foregoing ridge line and an orientation of a crystallographic axis of a semiconductor wafer, and measured an orientation of a crystallographic axis in a semiconductor wafer after epitaxial growth. As a result of it, it has been found out that the foregoing ridge line and the orientation of the crystallographic axis are completely consistent with each other.

Although the cause of the change of configuration of such dot marks is not certain, since the epitaxial growth makes a crystal having the same face orientation with that of the substrate grow on a single crystal substrate and nature such as atom density is different depending on face orientation, the epitaxial growth has anisotropy of growth whose rate is different depending on its face orientation. Therefore, the rate of the epitaxial growth in a minute point at which it rises from the surface of substrate is also different depending on its face orientation, as a result, it is considered that it grows into a poly pyramid configuration having a ridge line along the orientation of a crystallographic axis.

From these inference, it can be understood that a dot mark to be formed on the foregoing semiconductor before the epitaxial growth is not necessarily formed by laser marker, but it is also possible, for example, that a dot mark partially rising from the dot mark formation face may be formed by a procedure such as CVD and the like. In the case where a dot mark is used as the above described various management information, since the dot mark configuration before the epitaxial growth itself is needed to be in an excellent configuration in optical visibility, it is also required that a configuration of each dot mark is symmetry.

An aspect of the present invention has been performed based on a variety of knowledge described above, and it is a semiconductor wafer which is characterized in that a plurality of dot marks a part of each rising from a wafer surface to be a rising portion are formed in a group within a predetermined region of a semiconductor wafer, and dot marks of the foregoing group are divided into an epitaxial growth dot mark group in which an epitaxial growth layer is formed within the foregoing predetermined region and a non-epitaxial growth dot mark group in which an epitaxial growth layer is little formed.

As performed in the present invention, by forming dot marks having the above described configurations in a predetermined region of a semiconductor wafer, they are divided into a lump of epitaxial growth dot mark group and a lump of non-epitaxial growth dot mark group within the foregoing region. Then, when the dot mark most excellent in visibility in its non-epitaxial growth dot mark group is extracted, it has been appreciated that a straight line connecting its formation point of the mark and the center of the wafer directly indicates the orientation of a crystallographic axis. As a result, it is not necessary to form an orientation flat and V shaped notch after particularly measuring an orientation of a crystallographic axis using X-ray or the like.

Moreover, at the same time, in an epitaxial growth dot mark group, when the direction of its ridge line is sighted and recognized in an engineering manner, and a straight line connecting the formation point of the foregoing mark and the center of wafer and the foregoing ridge line are recognized to be parallel, it confirms that the direction of the foregoing straight line is the orientation of a crystallographic axis of a semiconductor wafer.

In this way, not only measurement device for an orientation of a crystallographic axis is not needed, but also a large number of integrated circuits are efficiently obtained since no cutting off portion of the semiconductor wafer exists. Moreover, since a dot mark indicating this orientation of a crystallographic axis does not have an inflection shaped portion in a limited area as an orientation flat, V shaped notch and the like do, a purified state is maintained without accumulating dust even through many steps of processes.

Preferably, the foregoing predetermined region is in the range of a predetermined central angle with the wafer center as its center. As previously described, when a single crystal layer is formed by the epitaxial growth on a mark formation surface of a semiconductor wafer on which a group of dot marks a part of each forming the rising portion have been formed within a predetermined region, dot marks formed in the semiconductor wafer after the epitaxial growth are divided into an epitaxial growth dot mark group consisted of dot mark group having a configuration different from the initial dot mark configuration and a non-epitaxial growth dot mark group consisted of dot mark group maintaining initial dot mark configuration.

On the other hand, as a result of the above described experiment, in a semiconductor wafer, it has been found out that the foregoing epitaxial growth dot mark group and non-epitaxial growth dot mark group repeatedly and periodically emerge along a peripheral area of the semiconductor wafer within a certain angle of circumference. For example, in a semiconductor wafer of the orientation of a crystallographic axis <100>, within an area of a central angle 45° from a given position, a non-epitaxial growth dot mark group and epitaxial growth dot mark group alternately emerge in a continuous manner. These non-epitaxial growth dot mark group and epitaxial growth dot mark group is not clearly discriminated by a certain boundary line, and dot marks are gradually changing within the foregoing region.

Therefore, even among the dot marks existing in the foregoing non-epitaxial growth dot mark group, there are some dot marks whose configurations are clear and other dot marks whose configurations are unclear, and further, there are still differences between dot marks whose configurations are clear. In the present invention, a dot mark having the clearest configuration among dot marks existing in the non-epitaxial growth dot mark group is selected and extracted, a straight line connecting the formation point of this dot mark and the wafer center is recognized as the orientation of the crystallographic axis.

However, as described above, in a semiconductor wafer of the orientation of the crystallographic axis <100>, since a lump of dot mark group consisted of non-epitaxial growth dot mark group and epitaxial growth dot mark group emerges per an area of its central angle 45°, relative to the wafer center, a plurality of crossing straight lines (four lines) exist. Therefore, it cannot be simply decided that directions of those straight lines indicate the orientations of a crystallographic axis. Hence, as described above, among dot marks after the epitaxial growth, a dot mark at which its poly pyramid configuration and ridge line are clearly formed is selected, the foregoing straight line which is parallel to the foregoing ridge line is found, and the orientation of the crystallographic axis can be precisely specified by specifying the direction of its straight line indicating the orientation of the crystallographic axis.

Also preferably, a formation region of the foregoing dot mark group is specified in such a manner that the foregoing group of dot marks are formed at the beveling portion of the rear face of a wafer circumferential face. Upon fabricating a semiconductor device, a variety of processes such as various forming of film, etching, chemical polishing, printing metal wiring are provided. Although the processed surface is mainly wafer surface, the influence of various processing liquids is also exerted on the front and rear sides of the wafer circumferential face. Moreover, wafer circumference tends to get abraded, even only slightly, due to interference with other members such as cassette, robot and the like. Furthermore, finally, the back face of a semiconductor wafer is largely ground.

On the other hand, in a wafer circumferential face, beveling is performed on the front and rear sides while its central portion remains. Even in this beveling region of the front and rear sides, there are differences in the influences due to a variety of processing steps described above. In general, the beveling region of the rear side receives little influence due to the foregoing processing steps. Therefore, if the dot marks in the present invention can be formed in the beveling region of this rear side, the foregoing mark may be continuously utilized until the final stage of a semiconductor fabrication.

And yet, if the dot mark is a large dot mark whose length parallel to the mark formation face is 100 to 200 μm like a conventional dot mark, since the number of marks which can be marked on the beveling region of the rear side is limited, it is impossible to write large amounts of information. Therefore, if large amounts of information are to be written in such small region, a size of the mark itself has to be minute inevitably. And also, the mark has to have sufficient visibility to be precisely read even if this minute mark is read.

As for the dot mark in the present invention, since the dot mark itself is not in an open form of concave-in shape as conventional one, and the dot mark has a configuration such that a portion, usually a center portion, thereof rises upward from the mark formation face. Therefore, for example, as specifically described in Japanese Patent Application No. 10-334009, which is a prior application of the present application, even if the dot mark is extremely minute such that the largest length parallel to the mark formation face is 1 to 15 μm, it is extremely excellent in visibility. And that, since its dimensions are minute, it is possible to write necessary and sufficient amounts of information even in the above described beveling region of the rear side. As a result, since the foregoing dot mark in the present invention is excellent also in optical visibility, it can be utilized not only for specifying the orientation of a crystallographic axis, but also for management information such as the processing history and the like as conventional.

Another aspect of the present invention provides a method of specifying the orientation of a crystallographic axis of a semiconductor wafer which includes the steps of: forming a plurality of dot marks a part of each rising from a wafer surface within a predetermined region of a semiconductor wafer; forming a single crystal over the entire surface of the foregoing semiconductor wafer by the epitaxial growth; dividing the foregoing dot marks formed within the foregoing predetermined region into an epitaxial growth dot mark group in which an epitaxial growth layer is formed and a non-epitaxial growth dot mark group in which an epitaxial growth layer is completely not or little formed; extracting the dot mark most excellent in visibility in the foregoing non-epitaxial growth dot mark group; and specifying the orientation of a crystallographic axis from the dot mark most excellent in visibility and the wafer center.

Although the dot mark formed before the foregoing epitaxial growth can be easily formed by means of laser marker of the prior application previously proposed by the present inventors, mark in a dot shape having the similar configuration can be formed also, for example, by other processing technologies such as CVD and the like. It should be noted that in the case where the foregoing dot mark is used not only for specifying the orientation of a crystallographic axis but also for management information such as processing history of a semiconductor wafer and the like as described above, it is desirable to form the dot mark by laser marker of the prior application. Moreover, as for the foregoing epitaxial growth technology employed in the present invention, since conventional widely known technologies may be employed, particular alteration for the present invention is not needed.

It should be noted that for a method of extracting the dot mark most excellent in visibility in non-epitaxial growth dot mark group in the present invention, for example, it may be performed by extracting the dot mark having the brightest luminance in the non-epitaxial growth dot mark group using photoelectric sensor.

### BRIEF DESCRIPTION OF THE DRAWINGS

FIG. 1 is an explanatory view schematically showing an example of laser marker for forming mark M′ in a dot shape having a specific configuration of the present invention.

FIG. 2 is a three dimensional view observed by AFM showing a typical configuration and an arrangement of the marks M′ in the dot shape formed by the foregoing marker.

FIG. 3 is a sectional view of FIG. 2.

FIG. 4 is a perspective view observed by AFM showing an example of the mark M′ in the dot shape according to an embodiment of the present invention.

FIG. 5 is a perspective view observed by AFM showing an example of the mark M′ in the dot shape according to another embodiment of the present invention.

FIG. 6 is an explanatory view observed by AFM showing a formation region of the foregoing mark M′ in the dot shape and a dot mark configuration within its region.

FIG. 7 is an explanatory view observed by AFM showing the foregoing dot mark configuration after the epitaxial growth of a growth layer of 1 μm in thickness.

FIG. 8 is an explanatory view observed by AFM showing the foregoing dot mark configuration after the epitaxial growth of a growth layer of 5 μm in thickness.

FIG. 9 is an explanatory view observed by AFM showing the foregoing dot mark configuration after the epitaxial growth of a growth layer of 10 μm in thickness.

FIG. 10A through FIG. 10D are plan views observed by AFM showing a configuration change depending on thickness of an epitaxial growth layer of the mark in the dot shape rising at the center thereof formed on a semiconductor wafer surface by laser marker.

FIG. 11A through FIG. 11D are plan views of FIG. 10A through FIG. 10D, respectively.

### DESCRIPTION OF THE PREFERRED EMBODIMENTS

The preferred embodiments of the present invention will be specifically described below with reference to the accompanying drawings.

First, one preferred example of a laser marker used for forming rising mark configuration in a dot shape partially formed on a semiconductor wafer before the epitaxial growth of the present invention will be described below based on a laser marker disclosed in the above described prior application previously proposed by the present inventors.

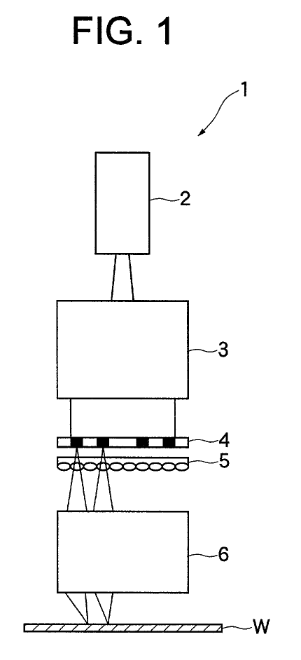

In FIG. 1, a laser marker 1 comprises a laser oscillator 2, a beam homogenizer 3 for smoothing an energy distribution of laser beam irradiated from the foregoing laser oscillator 2, a liquid crystal mask 4 for the foregoing laser beam being transmittably/non-transmittably driven corresponding to the display of a pattern, a beam profile conversion means 5 for forming and converting an energy density distribution of a laser beam corresponding to one pixel of the foregoing liquid crystal mask 4 into a predetermined distribution shape and a lens unit 6 for focusing a transmitted beam of the foregoing liquid crystal mask 4 on a semiconductor wafer surface per dot unit, the largest length of one dot of the foregoing liquid crystal mask 4 is 50 to 200 μm, and the largest length one dot focused by the foregoing lens unit 6 is 1 to 15 μm.

In the above described laser marker 1, a laser beam having a Gaussian shaped energy density distribution emitted from the laser oscillator 2 is formed, first through the beam homogenizer 3, into a top hat type energy density distribution shape in which peak values are approximately uniform. In this way, a laser beam whose energy density distribution is formed in a uniform manner is subsequently irradiated onto the surface of the liquid crystal mask 4. At this moment, the liquid crystal mask 4 is capable of displaying a predetermined marking pattern on the mask as widely known, the foregoing laser beam penetrates a part of the pixels in a light transmittable state within the same pattern display region. Energy density distribution of each transmitted light after divided and transmitted per each pixel is identical with the shape formed by the foregoing beam homogenizer 3 and is uniformly distributed.

The foregoing beam homogenizer 3 is, for example, a general term for optical parts for forming a laser light having an energy density distribution in a Gaussian shape into a smoothed energy density distribution. As these optical parts, for example, fly eye lens, binary optics and cylindrical lens are used, and there are a method of irradiating in a lump on its mask, or a method of scanning on the mask by mirror drive using actuator such as a polygon mirror and a mirror scanner.

Now, in the present invention, pulse width of the foregoing laser beam is 10 to 500 ns as already described, and its energy density is controlled in the range of 1.0 to 15.0 J/cm². Preferably, it is controlled in the range of 1.5 to 11.0 J/cm². When a laser beam is controlled within such range, the above described dot mark having a specific configuration of the present invention can be formed.

In the present embodiment of the present invention, an area of the foregoing liquid crystal mask 4 to be irradiated once is 10×11 pieces in a dot number, which is irradiated in a lump by laser beam. Since in many cases, as for the dot number, such dot number cannot satisfy the entire dot mark number required, it is possible that mark pattern is divided into several sections, which are displayed on the liquid crystal mask in turn, while switching the section and combining them to form the whole mark pattern on the wafer surface. In this case, when focusing on the wafer surface, it is necessary to control and move the wafer or the irradiation position. As such control procedure, a variety of procedures, which is conventionally known, can be employed.

A laser beam in a dot unit transmitted through the above described liquid crystal mask 4 is subsequently irradiated in the beam profile converter 5. This beam profile converter 5 has arrays similarly in a matrix manner corresponding to the individual liquid crystal of the foregoing liquid crystal mask 4, which is arrayed in a matrix manner. Therefore, a laser beam transmitted through the liquid crystal mask 4 passes through the foregoing beam profile converter 5 per one dot in a one-to-one correspondence, and a laser beam of energy density distribution respectively smoothed by the beam homogenizer 3 is converted into an energy density distribution shape which is required to form a minute hole shape peculiar to the present invention by the beam homogenizer 3. Although the energy density distribution shape of the laser beam after transmitted through the liquid crystal mask 4 is converted by transmitting through the beam profile converter 5 in the present embodiment as described above, the laser beam may be directly introduced into the next lens unit 6 without converting the profile of the energy density distribution by the beam profile converter 5.

The laser beam transmitted through the beam profile converter 5 is narrowed by the lens unit 6, is irradiated at the predetermined position on the surface of a semiconductor wafer W, and dot marking required for the same surface is performed. In the present invention, the largest length of a pixel unit of the foregoing liquid crystal is defined as 50 to 2000 μm, the laser beam is narrowed to 1 to 15 μm on the surface of the semiconductor wafer W by the foregoing lens unit 6. Now, in the case where markings in a micron-unit are formed in a uniformed manner on a plurality of wafer surfaces, the distance adjacent between its marking face and condenser lens, and optical axis adjustment are required to be done in a micron-unit. According to this embodiment of the invention, as for focus detection, height measurement is performed in a confocal method generally used in laser microscopy and the like, this value is supplied to a minute positioning mechanism of the longitudinal direction of the lens as a feedback, and the positioning of focus is automatically performed. Moreover, in an optical axis adjustment and a positioning and adjustment of an optical constituent parts, a generally known method is employed, for example, through a guide light such as He—Ne laser and the like, adjustment is performed by screw adjustment mechanism and the like to be adapted for a pre-set reference spot. It will be sufficient that this adjustment is performed once at the time when it is built up.

As for mark M′ in a minute dot shape in the present embodiment of the present invention, the largest length of it is in the dimension range of 1 to 15 μm, and in consideration of the case where the peripheral of its rising portion is slightly depressed, its convex and concave dimension is in the range of 0.1 to 5 μm. In order to form a mark M′ in a dot shape in such dimensions, it is required that the length of one side per one dot of the above described liquid crystal mask 4 is 50 to 2000 μm not to occur a break of image formation at the irradiation point of the surface of the semiconductor wafer W due to resolution of a reduced lens unit and the like. Furthermore, turbulence of image formation on the surface of the semiconductor wafer is easily occurred by receiving the influence of peripheral light or unstability of the optical axis if the disposition interval between the foregoing beam profile converter 5 and the foregoing liquid crystal mask 4 is to large or too small. Hence, in the present embodiment, it is needed to set the disposition interval X between the foregoing beam profile converter 5 and the foregoing liquid crystal mask 4 into 0 to 10 times the largest length Y of one pixel unit of the foregoing liquid crystal mask 4. By setting the foregoing disposition interval in this range, the image formation irradiated on the surface of the wafer becomes clear.

The above described beam profile converter 5 is an optical constituent parts for converting an energy density distribution smoothed by the foregoing beam homogenizer 3 into the optimum energy density distribution shape to obtain a dot shape peculiar to the present invention, and for converting an energy density distribution profile of incident laser light into a given shape by making diffraction phenomenon, refraction phenomenon, optical transmissivity at a laser irradiation point or the like are differentiated optionally. As its optical parts, for example, holographic optical element, convex type micro lens array or liquid crystal itself is listed, these are arranged in a matrix manner and used as the beam profile converter 5.

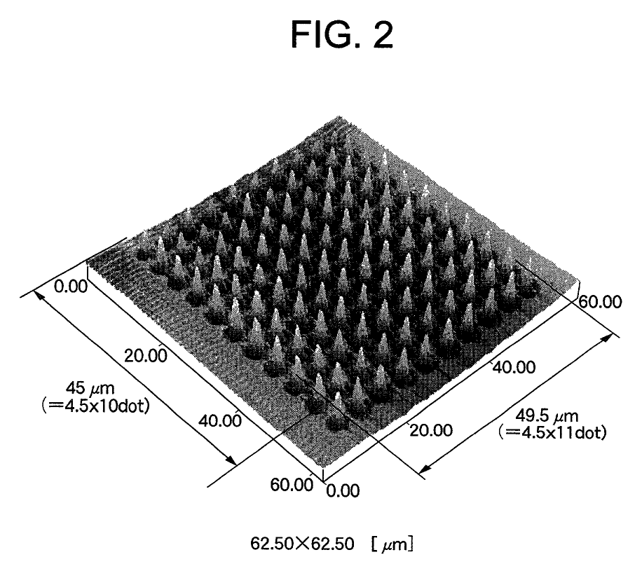

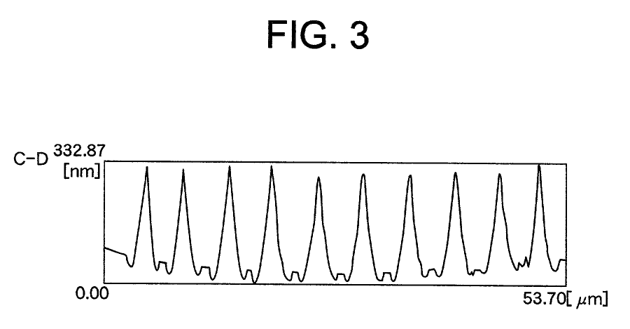

FIG. 2 and FIG. 3 show an example of a typical shape and arrangement of marks M′ in a dot shape initially formed on the surface of a semiconductor wafer W by the above described laser marker. It should be noted that FIG. 2 is a three dimensional view observed by AFM and FIG. 3 is a sectional view of FIG. 2. According to the present embodiment, a dimension of each optical image formed on the surface of the semiconductor wafer W is a square of 3.6 μm one side, and each dot interval has been defined as 4.5 μm. As it can be understood from these figures, a mark M′ in an approximately conical dot shape is formed per laser beam divided corresponding to each pixel of the liquid crystal mask 4 on the surface of the semiconductor wafer W, moreover, these marks M′ in a dot shape are arrayed orderly in 11 pieces×10 pieces arrays, respective heights are approximately equal. This is the reason why an energy density distribution of laser beam irradiated to the liquid crystal mask 4 is equally smoothed by the beam homogenizer 3.

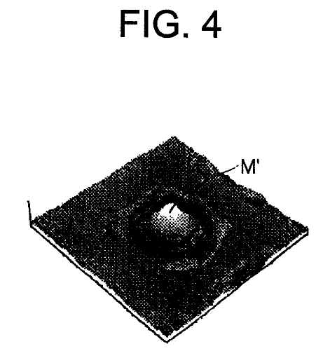

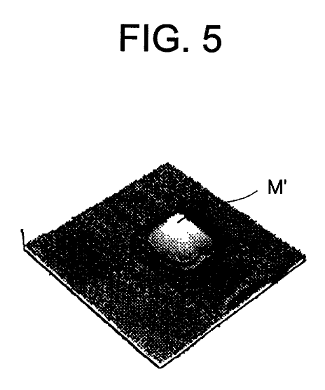

FIG. 4 and FIG. 5 show a mark configuration in a peculiar dot shape formed under the specification described below by the above described laser marker 1 employed by the present embodiment. The specification of the foregoing laser marker 1 is defined as follows:

Laser medium: Nd, YAG laser

Laser wavelength: 532 nm

Mode: TEMOO

Average output: 4W@1 KHz

Pulse width: 100 ns@1 KHz

where the wavelength of laser beam is defined as 532 nm. However, the wavelength of laser beam is not defined uniformly.

Moreover, as a laser beam used in the present embodiment, laser beams which are oscillated by YAG laser oscillation device, the second higher harmonic of YVO4 laser oscillation device, titanium sapphire laser oscillation device and the like may be used.

FIG. 4 and FIG. 5 are perspective views showing a configuration of each dot mark M′ obtained by optical image in a square shape whose one side is 4 μm and 9 μm. According to these figures, a shallow concave portion in a ring shape is formed in the peripheral of a dot shaped mark M′, and its central portion has the rising portion in an approximately conical shape rising highly upward. In this dot configuration, since a portion having an extremely high luminance at its rising portion is generated, the luminance difference compared to the peripheral becomes large, sufficient visibility is secured. A mark configuration in the dot shape and the dot marking method before the epitaxial growth of this embodiment has a peculiar configuration in which the central portion rises, and a mark configuration in dot shape cannot be found in conventional ones, in addition to that, it can form a single minute mark M′ in a dot shape having a uniform configuration of 3/20 to 1/100 dimensions of those of conventional one and in which it is arranged precisely and orderly in the region per each dot unit of the surface of the semiconductor wafer.

Moreover, since a mark M′ in a dot shape according to the present embodiment is made much more minute compared to the dimensions of the conventional dot mark as previously described, and that, the boundary with a neighboring mark M′ in the dot shape can be clearly distinguished, many marks M′ in the dot shape can be formed in the same area, not only its marking area largely increases, and at the same, degree of freedom increases upon selection of the marking area.

In the present invention, after forming the mark M′ in the dot shape thus obtained on the predetermined region of the semiconductor wafer, a crystal layer consisted of a new single crystal on the wafer surface having the mark by the epitaxial growth. According to the present embodiment, the foregoing predetermined region denotes a notch formed on a circumferential face of the semiconductor wafer W and a beveling region of the front and rear sides of the circumferential face, and many dot marks are formed in this region.

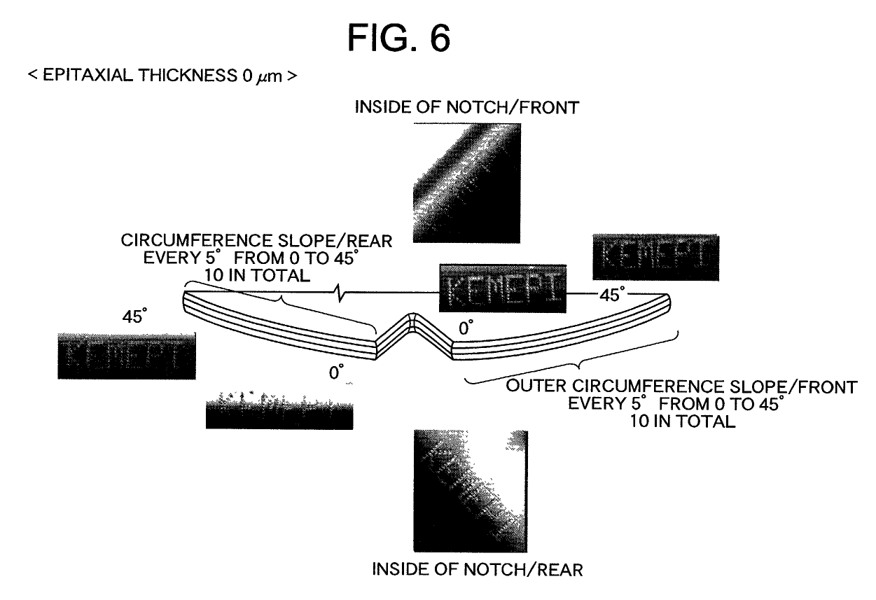

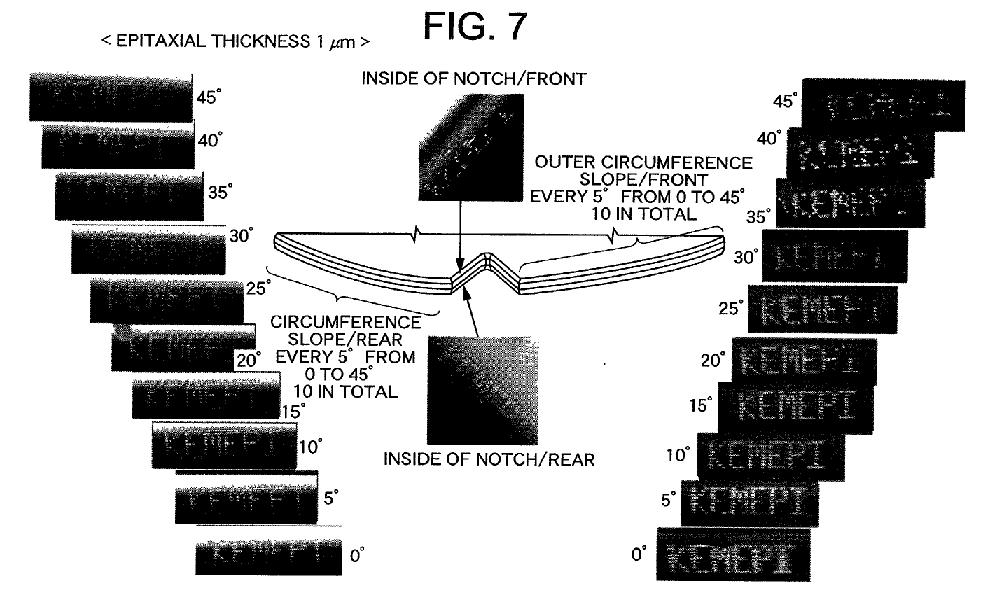

FIG. 6 through FIG. 9 show a region in which the foregoing dot mark M is formed and a change of a dot mark configuration depending on the layer thickness of the single crystal when the same single crystal is formed on the entire wafer surface by the epitaxial growth after forming the dot mark M′ in the same region by the above described laser marker. FIG. 6 shows the configuration of the dot mark M′ formed in the same region by laser marker. In the present embodiment, roman letters consisted of a set of many dot marks are written on the beveling portion (slope portion) of the front and rear sides which is formed inside face of the foregoing notch, and many dot marks M′ constituting the letters identical with the letters described above are written on the beveling portion (slope portion) of the front and rear sides of circumference spanning over respective 45° of angle of circumference from an open ends of the notch. As for the letters formed on the beveling portion (slope portion) of the front and rear sides of the circumference spanning over the foregoing 45° of angle of circumference, the same letters are written at intervals of 50 within angle of circumference 0 to 45°, assuming that the position of the each open end of the foregoing notch as 0°. FIG. 7 through FIG. 9 show a change of the configuration of the dot mark M in each region when a single crystal is formed into the layer thickness of 1 μm, 5 μm and 10 μm by the epitaxial growth on the entire surface of the semiconductor wafer W on which the foregoing dot mark is formed.

In FIG. 6, a cutout in a V shape formed on a circumference of the semiconductor wafer W forms a notch indicating an orientation of a crystallographic axis, and a direction connecting the center of internal vertex of the same notch and the center of the semiconductor wafer W indicates the orientation of the crystallographic axis. In the present embodiment, roman letters consisted of a set of many dot marks are written on the beveling portion (slope portion) of the front and rear sides which is formed inside face of the foregoing notch, and many dot marks M′ constituting the same letters as the letters described above are written on the beveling portion (slope portion) of the front and rear sides of circumference spanning over respective 45° of angle of circumference from each open end of the same notch. As for the letters formed on the beveling portion (slope portion) of the front and rear sides of the circumference spanning over the foregoing 45° of angle of circumference, the same letters are written at every 5° of angle within angle of circumference 0 to 45°, assuming that the position of the open end of the foregoing notch as 0°.

As is apparent from FIG. 6, the visibility of the dot marks M′ are at the same extent in all when written by the above described laser marker, and each letter can be read with extreme clearness.

On the other hand, referring to FIG. 7 in which a single crystal having a layer thickness of 1 μm is formed by the epitaxial grouth on the surface of the semiconductor wafer W shown in FIG. 6, a configuration of the dot mark M formed on the beveling portion of the rear side of the wafer of notch and circumference is overall more excellent in visibility compared to that of the dot mark M formed on the front side. Referring to luminance difference measured by photoelectric sensor, luminance of the dot mark M formed in the range of 15° to 20° of the rear sides of the notch and circumference is the largest.

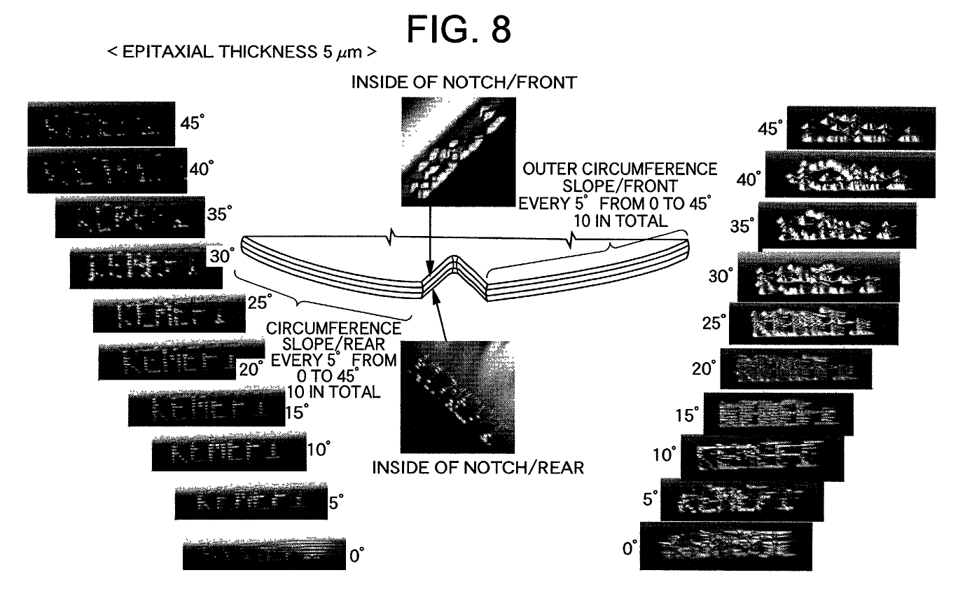

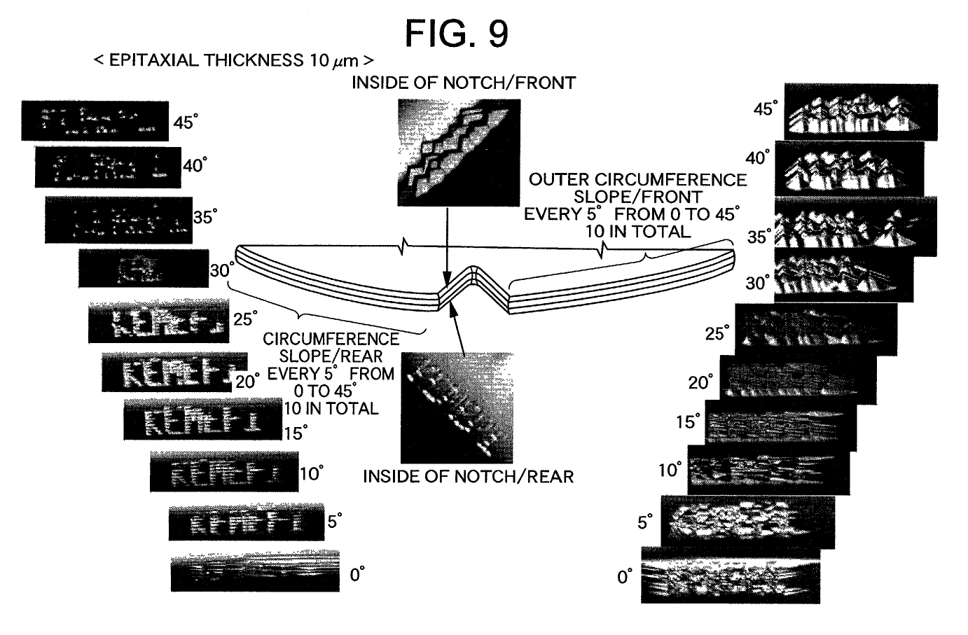

Referring to FIG. 8 in which the layer thickness by the epitaxial growth is made 5 μm, a configuration of the dot mark M formed on the beveling portion of the surface side is completely deformed, and it is impossible to read any letter information. On the other hand, as for the dot mark M formed on the beveling portion of the rear side, the letter formed in the range of 10° to 30° has the visibility in some extent, however, the region most excellent in optical visibility was the notch and the range of 15° to 20°. Referring to FIG. 9 in which the layer thickness by the epitaxial growth is made 10 μm, a configuration of the dot mark M formed on the beveling portion of the front and rear sides are both largely deformed, it is impossible to read any letter information.

For example, dots are formed at intervals of 1° in the range of ±45°, and the orientation of a crystallographic axis can be determined depending on the growth extent of the dots. Thus, although 4 ways of orientations exist in the ranges of 0° to 90°, 90° to 180°, 180° to 270° and 270° to 360° , all of these 4 ways of orientations of crystallographic axis have symmetry each other. In this case, although the precision is 1°, if further precise precision is required, the formation of dot requires smaller intervals.

According to the experiment results described above, it is determined that a dot mark in a rising shape is previously formed on the mark formation face as already described, and a single crystal is formed thereon by the epitaxial growth, then the dot mark configuration is changed into a poly pyramid or a truncated poly pyramid, and its ridge line direction indicates the orientation of the crystallographic axis.

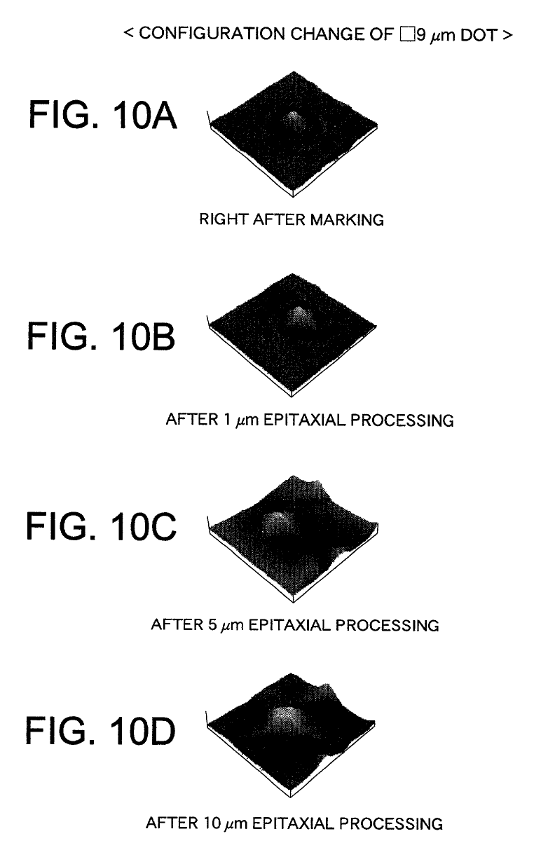

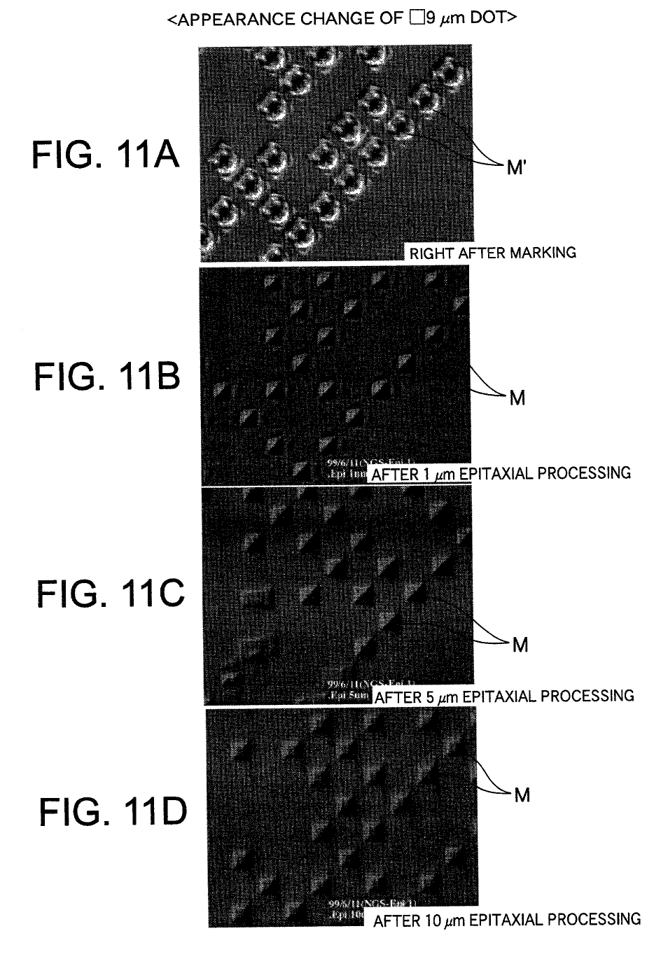

FIG. 10A through FIG. 10D and FIG. 11A through FIG. 11D show a state of change of a configuration after the epitaxial growth to the dot mark obtained by image-forming in a square of 9 μm each side on the surface of a Si semiconductor wafer by the above described laser marker. FIG. 11A through FIG. 11D show the state of change of each dot mark configuration when a dot mark group is optically sighted and recognized in the plan view, and FIG. 10A through FIG. 10D show the state of change of each dot mark configuration by a perspective view.

As is understood from the FIG. 10A and FIG. 11A, the rising mark configuration in a dot shape obtained is not of rectangular pyramid but only of conical shape, it indicates that the shape is necessarily analogized with an optical image formed by laser beam in a plan view. Moreover, in the present embodiment, the thickness of each crystal layer formed by the above described epitaxial growth method is defined as three ways of 1 μm, 5 μm and 10 μm, a change of its dot configuration is shown in FIG. 10B through FIG. 10D and FIG. 11B through FIG. 11D.

Herein, the epitaxial growth according to the present embodiment employs the chemical vapor deposition (CVD) method. In this epitaxial growth, a wafer is placed on SiC coated carbon pedestal which is generally a heating body, putting it into a growth oven, the wafer is heated in a high temperature of about 1000 to 1200° C. in the hydrogen atmosphere by a high frequency method, a resistant heating method or a lamp heating method. Subsequently, the wafer surface is gas etched in the range of 0.1 to 0.4 μm by chlorine or sulfur hexafluoride gas diluted by hydrogen, and a refined silicon surface is exposed.

After this gas etching is finished, a mixed gas of reactive gas such as monosilane or the like and dopant gas is made to flow into the oven, silicon single crystal is grown on the wafer surface by the epitaxial growth. At this moment, although the thickness of an epitaxial growth layer is determined by growth time, since fundamentally, concentration, flow volume, flow rate, temperature, pressure and the like of the reactive gas, the growth thickness and time are set after precisely grasping relationship of these factors.

As apparent from these figures, regardless of the dimension of the mark M′ in the dot shape initially formed on the semiconductor wafer surface, it can be understood that the configuration of the vertex of the growth layer by the epitaxial growth is changed into a smooth face in accordance with an increase of the layer thickness of the growth layer. Further in detail, in the case of the thickness of the epitaxial growth layer being in the range of 1 to 5 μm, it has a pyramid configuration having the complete square base, and although ridge lines extending from its vertex are clear and forms a cross shape, the vertex of the foregoing pyramid configuration is changed into a truncated pyramid having the rectangular base in which the vertex is cut off in a horizontal direction in the case of a layer thickness being in the range of 5 to 10 μm.

Now, it should be noteworthy that in all dot marks M formed on the same wafer surface, the direction of their ridge lines are consistent, and moreover, the direction of extended line of its ridge line and the orientation of the crystallographic axis of the semiconductor wafer is consistent. Therefore, if a procedure of determining the orientation of the crystallographic axis by the foregoing ridge line is used at the same time in addition to a procedure of determining the orientation of a crystallographic axis by the visibility of dot mark M based on the above described mark formation region, the above described mix-up will not occurs.

Returning to the above described FIG. 8 and FIG. 9, dot mark configuration in the range of right side 45° adjacent to the notch center in these figures represents an apparent pyramid shape having the rectangular base and there are rows of these dot marks M. Observing each dot mark unit, since ridge lines extend in parallel and the direction is in parallel with a straight line connecting the above described notch center and the wafer center, the orientation of the crystallographic axis of the semiconductor wafer can be specified by the foregoing straight line. The present invention, in the first place, does not need the notch, thus even in the case where the notch is absent, precise orientation can be specified by the foregoing procedure of determining the orientation of the crystallographic axis by the foregoing ridge line in addition to the above described procedure of determining the orientation of a crystallographic axis by the visibility of dot mark M based on the mark formation region.

It should be noted that the dot mark representing the previously described apparent pyramid shape having the rectangular base emerges similarly at intervals of 90° from the position of the foregoing dot mark configuration. And since all these dot marks have symmetry configuration, if the phenomenon is utilized, more precise orientation of a crystallographic axis can be determined.

Moreover, it can be understood that in FIG. 7 and FIG. 8, even in the case of a dot mark M after the epitaxial growth, a dot mark M formed in the area of 0° and 45°, for example, has a configuration which can be read sufficiently as a usual management information and the like. From this fact, the above described dot mark M can be used as a mark, not only for specifying the orientation of the crystallographic axis, but also for conventional management information and the like. In this case, it will be possible that by utilizing its symmetry, changing the phase of dot mark groups having the same information by turning 90° and a plurality of groups are formed on circumferential faces of the wafer.

What is claimed is:

1. A semiconductor wafer, wherein a group of a plurality of dot marks a part of each being a rising portion rising from wafer surface is formed within a predetermined region of a semiconductor wafer,
the one group of dot marks is divided into an epitaxial growth dot mark group in which an epitaxial growth layer is formed within the predetermined region and a non-epitaxial growth dot mark group in which little epitaxial growth layer is formed.

2. A semiconductor wafer according to claim 1, wherein said predetermined region is in a range of the predetermined central angle with a wafer center as its center.

3. A semiconductor wafer according to claim 1 or 2, wherein said one group of dot marks is formed on a beveling portion of a rear side of a wafer circumferential face.

4. A method of specifying an orientation of a crystallographic axis of a semiconductor wafer, the method comprising the steps of:
forming a plurality of dot marks a part of each rising from a wafer surface within a predetermined region of the semiconductor wafer;
forming a single crystal on entire surface of the semiconductor wafer by the epitaxial growth;
dividing the dot marks formed within the predetermined region into an epitaxial growth dot mark group in which an epitaxial growth layer is formed and a non-epitaxial growth dot mark group in which little epitaxial growth layer is formed;
extracting the dot mark most excellent in visibility in the non-epitaxial growth dot mark group; and
specifying an orientation of a crystallographic axis from the dot mark most excellent in visibility and the wafer center.
